(19) United States
(12) Patent Application Publication
(10) Pub. No.: US 2005/0045370 A1
(43) Pub. Date: Mar. 3, 2005

(54) Printed board and method of displaying an identification mark on the same

(76) Inventor: Tatsuo Katayama, Takefu-city (JP)

Correspondence Address: FLYNN THIEL BOUTELL & TANIS, P.C., 2026 RAMBLING ROAD, KALAMAZOO, MI, 49008-1699, US

(21) Appl. No.: 10/931,892

(22) Filed: Sep. 1, 2004

(30) Foreign Application Priority Data
Sep. 2, 2003 (JP) 2003-310094

(51) Int. Cl. H05K 1/00

(52) U.S. Cl. 174/250

(57) ABSTRACT

The invention is intended to provide a printed board wherein a stable soldering processing can be executed on the basis of weight distribution in the printed board, and storage as well as control can be implemented on the basis of the weight distribution, and a method of displaying the identification mark on the printed board. The weight distribution in the printed board is found on the basis of weight information and reference position information, on circuit components to be mounted on the printed board, and mount information on the circuit components. That is, on the basis of the reference position information and the mount information, the coordinates of the center positions of the respective circuit components, on the printed board, are calculated, and weights of the respective circuit components are assigned to the coordinates of center positions of the respective circuit components, thereby finding the weight distribution. Identification marks 2 to 4, indicating heavy parts in terms of the weight distribution, respectively, are displayed on the printed board.

### FIELD OF THE INVENTION

The invention relates to a printed board on which an IC, and circuit components, such as transistors, and so forth, are mounted.

### BACKGROUND OF THE INVENTION

With advances in development of electronization, various products including electronic equipment, such as a TV, a video recorder, and so forth, have come to use a number of circuit components, and these circuit components are mounted on a printed board rectangular in shape to be thereby wired and interconnected.

As the products have recently become more compact in size, the printed board has decreased in size, and high-density mounting is applied thereto because a great many circuit components have come to be mounted thereon based on the surface mount technology. As a result, there has arisen a problem of how to solder each of the circuit components in a solder tank with reliability after mounting the circuit components on the printed board.

For example, it is described in Patent Document 1,i.e., Utility Model Registration No. 60172/1994, that a warp-stop guide is disposed above a solder tank, and along a conveyance direction of a printed board, in such a way as to traverse the solder tank, and the middle part of the printed board is supported by the warp-stop guide when the printed board passing through a soldering area, thereby preventing the printed board from being bent due to its own weight. Also, in Patent Document 2, i.e., JP-A No. 232702/1994, it is described that an insertion direction display part showing a direction in which a printed wiring board is to be inserted into a solder tank is formed on top of the printed wiring board, so that pats directions and component directions are always constant in relation to the flow of solder in the solder tank.

In Patent Document 1, and Patent Document 2, respectively, attention is focused on the problem of warpage due to the weight of the printed board itself, and relationships between the flow of solder in the solder tank and circuit components, however, with the adoption of flexible manufacturing systems for products, the circuit components mounted on the printed board are mounted in various combinations, and layout of the circuit components often vary on a case-by-case basis. Accordingly, the descriptions of Patent Document 1, and Patent Document 2, respectively, are less than satisfactory to rapidly cope with those printed boards variously patterned as described above.

For example, depending on where a power supply transformer occupying a large proportion of the total weight of a printed board is laid out, horizontal distribution of weight in the printed board, will considerably vary. Further, one of primary causes for solder running round to the upper surface of the printed board, in a solder tank, is that when a part of the printed board, on the leading end side, in a conveyance direction thereof, is heavier, the part thereof, on the leading end side, is warped downward to be thereby tilted. Hence, it is important to accurately recognize weight distribution in printed boards with a wide variety of layouts, respectively, before carrying out a soldering processing.

### SUMMARY OF THE INVENTION

It is therefore an object of the invention to provide a printed board wherein a stable soldering processing can be executed on the basis of weight distribution in the printed board, and storage as well as control can be implemented on the basis of the weight distribution, and a method of displaying an identification mark on the printed board.

A printed board according to the invention is a printed board with circuit components mounted thereon, wherein there is displayed an identification mark related to weight distribution in the printed board as a whole, calculated on the basis of weight information and reference position information, on the circuit components, and design information concerning respective mount positions of the circuit components. Further, the identification mark is displayed in relation to the weight distribution, along a conveyance direction of the printed board, in a solder tank. Still further, the identification mark may be displayed in a part along one side of the printed board, indicating the leading end side or the rear end side, in the conveyance direction. Yet further, the identification mark may be displayed so as to pass through the heaviest part in terms of the weight distribution, thereby indicating the conveyance direction.

A method of displaying an identification mark, according to the invention, comprises the steps of:
reading weight information and reference position information, on circuit components to be mounted on a printed board, and design information concerning mount positions of the respective circuit components;
calculating set position information on the printed board, on the basis of the design information and the reference position information;
calculating weight distribution information of the printed board, on the basis of the set position information and the weight information; and
displaying the identification mark on the printed board, on the basis of the weight distribution information.

With the printed board according to the invention having such a configuration as described above, since the weight distribution in the printed board as a whole is calculated on the basis of the weight information and the reference position information, on the circuit components to be mounted on the printed board, and the design information concerning the respective mount positions of the circuit components, the weight distribution can be accurately found, and by displaying the identification mark in relation to the weight distribution, setting corresponding to the weight distribution in the printed board can be implemented with ease.

If the identification mark is displayed in relation to the weight distribution, along the conveyance direction of the printed board, in the solder tank, this will enable optimum setting along the conveyance direction to be implemented promptly and precisely, so as to correspond to the weight distribution in respective printed boards even in the case of printed boards with variously patterned layouts, respectively. By displaying the identification mark in the part along one side of the printed board, thereby indicating the leading end side or the rear end side of the printed board, in the solder tank, along the conveyance direction, it becomes possible to easily recognize which is heavier, the leading end side or the rear end side, so that setting can be made precisely such that a heavier side of the printed board is on the rear end side thereof, in the conveyance direction. Accordingly, when conveying the printed board, it is possible to prevent a part of the printed board, on the leading end side, to be warped downward due to weight balance so as to be tilted, thereby checking solder to run round to the upper surface of the printed board. Further, by displaying the identification mark so as to pass through the heaviest part in terms of the weight distribution to thereby indicate the conveyance direction of the printed board in the solder tank, it is possible to easily recognize a position on the printed board, most susceptible to bending, during conveyance of the printed board, so that by adjusting a position of a guide provided in the solder tank so as to correspond to the position on the printed board, most susceptible to bending, the printed board with a varying layout can be conveyed in the solder tank while keeping the printed board substantially in a constant state.

In addition, since the identification mark is displayed in relation to the weight distribution, it is possible to easily recognize the heavier side of the printed board when transporting or storing the printed board in a standup condition, so that with all the printed boards, setting can be made such that a heavier side thereof is precisely on the lower side, thereby enabling the printed boards to be transported or stored in a stable state.

Further, with the method of displaying the identification mark, according to the invention, since the identification mark is displayed on the basis of the weight distribution information as calculated from the weight information and the reference position information, on the circuit components to be mounted, and the design information concerning the respective mount positions of the circuit components, it becomes possible to accurately display the identification mark so as to correspond to a balance position of a printed board with a varying layout. Further, since the design information is prepared in a design stage while the weight information and the reference position information, on the circuit components to be mounted, are kept registered beforehand, the weight distribution can be determined before printing by the printed board, so that display of the identification mark can be executed in conjunction with the printing of the printed board. In addition, as it is possible to make a decision in the design stage, as appropriate, on where and in which shape the identification mark is to be displayed, the identification mark in a shape easier to be recognized can be displayed at a position easier to be recognized depending on the layout of the printed board. Furthermore, there is hardly any need for an additional step of processing, such as actual measurement of weight after mounting on the printed board.

### BRIEF DESCRIPTION OF THE DRAWINGS

FIGS. 1(A), 1(B) and 1C) are schematic plan views showing embodiments of an identification mark according to the invention;

FIGS. 2(A), 2(B) and 2(C) are schematic illustrations concerning display of the identification mark according to the embodiment of the invention;

FIG. 3 is a schematic plan view showing a mechanism for soldering;

FIGS. 4(A), 4(B) and 4(C) are schematic sectional views showing a printed board being conveyed;

FIG. 5 is a schematic block diagram showing an apparatus for displaying the identification mark.

FIG. 6 is a schematic illustration concerning reference positions of circuit components;

FIG. 7 is a schematic illustration concerning the coordinates of the center positions of the respective circuit components on the printed board; and

FIG. 8 is a flow chart concerning display processing of the identification mark.

### PREFERRED EMBODIMENTS OF THE INVENTION

An embodiment of the invention is described in detail hereinafter. However, the embodiment of the invention described hereinafter is preferred specific examples for carrying out the invention, and various technical limitations are made thereto, but it is to be pointed out that the invention is not limited thereto unless specifically and explicitly described otherwise in the following description.

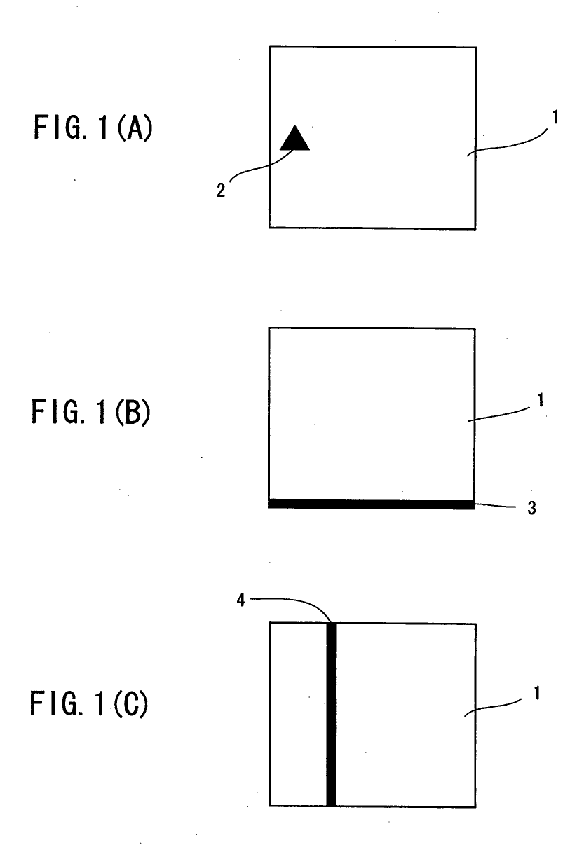

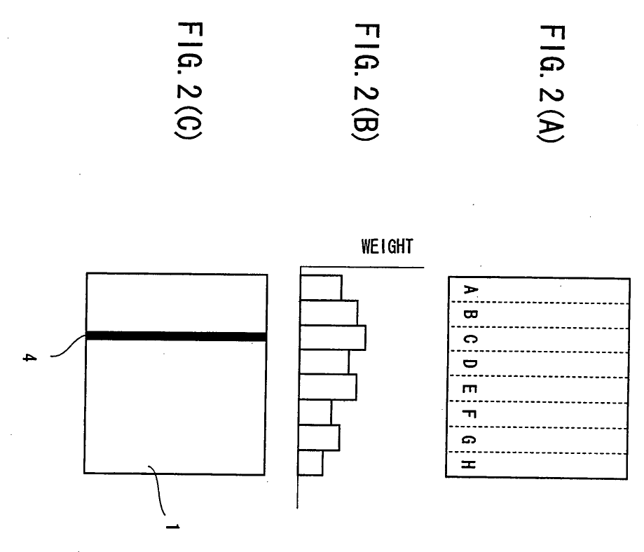

FIG. 1 is a schematic plan view showing the embodiment of the invention. Identification marks 2 to 4, each are displayed on the upper surface of a printed board 1. Circuit components mounted on the printed board 1 are omitted for brevity in explanation. In FIG. 1(A), the identification mark 2 in the shape of a triangle is displayed substantially in the central part of the printed board 1, in the vertical direction along the plane of the figure. Further, the vertex of the triangle, pointing upward, indicates that the upper half portion of the printed board 1 is lighter in weight than the lower half portion thereof, that is, in terms of weight distribution, the lower half portion is heavier. In FIG. 1(B), the identification mark 3 in a band-like shape is displayed in a part along one whole side of the printed board 1. In this case, the identification mark 3 may be displayed in the part along one side of the printed board 1, in a heavier half portion of the upper half and lower half portions as with the case shown in FIG. 1(A), or in a part along one side of a region heaviest in terms of weight distribution among four regions formed by diagonally partitioning the surface of the printed board 1. In FIG. 1(C), the identification mark 4 in a band-like shape is displayed so as to be in parallel with one of the sides of the printed board 1. Further, a display position of the identification mark 4 is displayed such that the identification mark 4 passes through a region heaviest in terms of weight distribution (weight distribution as shown in a bar graph of FIG. 2(B)) among eight regions A to H, formed by partitioning the surface of the printed board 1 as shown in FIG. 2(A) (refer to FIG. 2(C)).

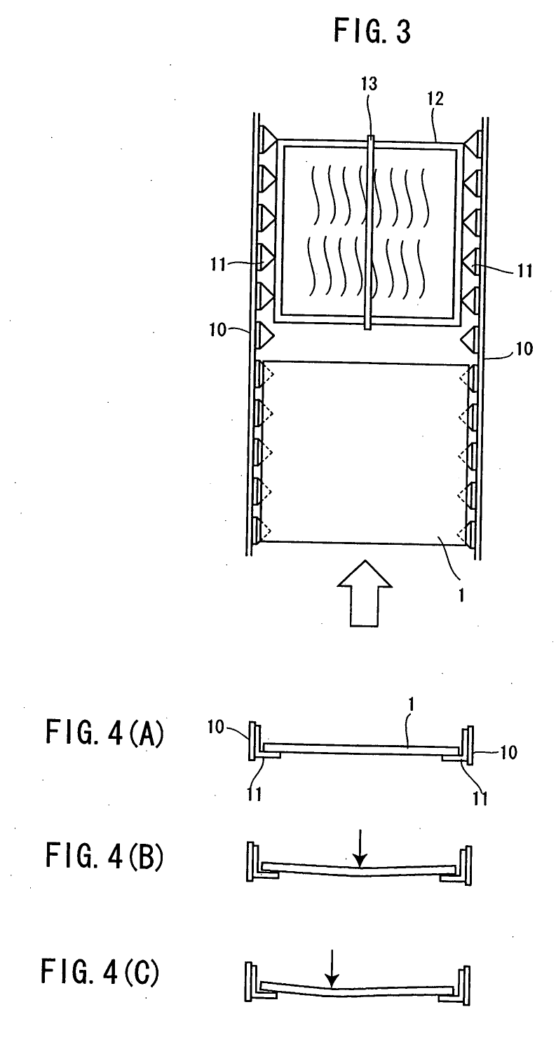

FIG. 3 is a schematic plan view showing a mechanism for conveying the printed board 1 into a solder tank. The printed board 1 is conveyed by a pair of conveyer belts 10, disposed so as to be in parallel with each other. The pair of the conveyer belts 10 are disposed such that respective conveyance faces thereof are oriented along the vertical direction, and a conveyance path is provided between both the conveyance faces.

Further, a multitude of pawls 11 are fixedly attached to the respective conveyance faces, and are horizontally protruded toward the conveyance path so as to be able to support the printed board 1. Meanwhile, a solder tank 12 is disposed below the conveyance path, and as with the conventional case, molten solder is housed in the solder tank 12, circulating therein in such a way as to form an upward jet flow. A guide 13 is installed on the upper end of the solder tank 12, so as to be extended along a conveyance direction. The guide 13 has notches formed so as to fit on the upper end of the solder tank 12, and is slidable in a direction orthogonal to the conveyance direction, so that the guide 13 can be set to an optional position on the upper end of the solder tank 12.

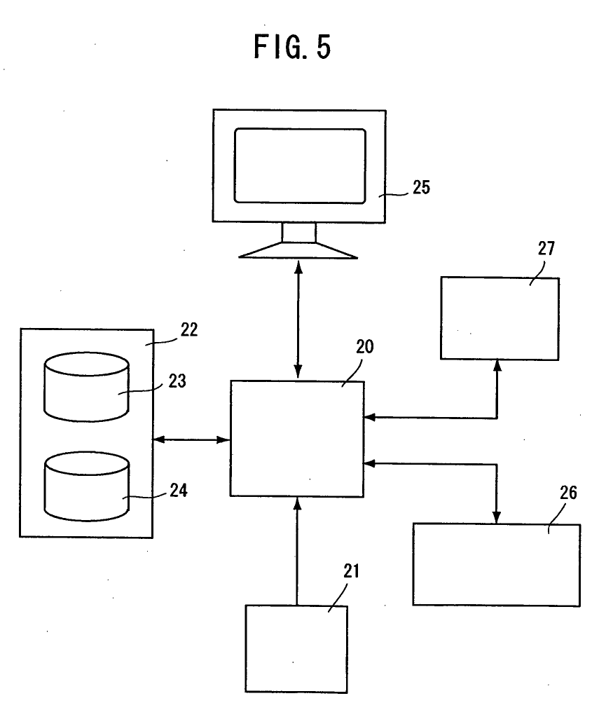

The printed board 1 is conveyed in the conveyance path between the pair of the conveyer belts 10, in the upward direction along the plane of the figure while being supported with the pawls 11. During conveyance of the printed board 1, both edges thereof are supported with the pawls 11, respectively, so that the printed board 1 is in a downward bent state due to the weight of circuit components mounted thereon. As shown in FIG. 4, the printed board 1 in a state with no circuit components mounted thereon is substantially in a straight line form as seen from one side thereof as shown in FIG. 4(A), however, in the case of the printed board 1 in a state with circuit components mounted thereon, the heaviest part thereof, indicated by the arrow, is bent in a downward warped state as shown in FIGS. 4(B), and 4 (C).

Accordingly, when conveying the printed board 1 in the solder tank 12, if the identification mark 2 is displayed as shown in FIG. 1(A), it need only be sufficient to set such that the printed board 1 is conveyed in the upward direction along the plane of the figure, as pointed by the vertex of the triangle, since the upper half portion is lighter in weight. By so doing, although the lower half portion of the printed board 1 undergoes large warpage as the same is heavier, it is possible to prevent solder from running around to the upper surface of the lower half portion, as it is on the rear end side, in the conveyance direction. Further, if the identification mark 3 is displayed as shown in FIG. 1(B), it need only be sufficient to set such that a side of the printed board 1, displayed with the identification mark 3 is on the rear end side, in the conveyance direction, that is, the printed board 1 is conveyed in the upward direction along the plane of the figure. Further, if the identification mark 4 is displayed as shown in FIG. 1(C), setting is made such that the printed board 1 is conveyed so as to move along the identification mark 4, and at the same time, positioning of the guide 13 is made by sliding the same so as to match the identification mark 4 at the time of conveyance of the printed board 1, so that when the printed board 1 undergoes warpage, a heaviest part thereof comes to be at the lowest position, whereupon the guide 13 comes to act in such a way as to push the heaviest part upward, thereby enabling the guide 13 to be set with reliability to a position where solder is most likely to run around to the upper surface of the printed board 1.

Next, a method of displaying an identification mark is described hereinafter. FIG. 5 is a block diagram showing an apparatus configuration for displaying the identification mark. A CPU 20 controls the apparatus as a whole, and a program, and so forth, necessary for the control of the apparatus, are stored in a ROM 21. A memory 22 is provided with component information DB23 for accumulating data concerning circuit components mounted on a printed board, and mount information DB24 for accumulating data concerning mounting of components to be mounted, as set upon designing the printed board. A balance position on the printed board, calculated by the CPU 20, display position, shape, and so forth of the identification mark are displayed in images on a monitor 25. A printing unit 26 prints a finally decided identification mark on the printed board. Data necessary for controlling calculation are inputted from an input unit 26.

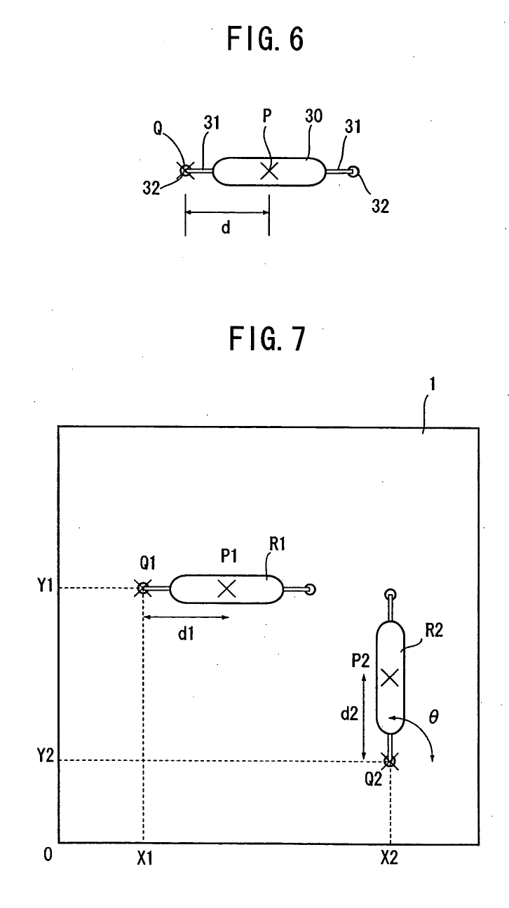

Various information on the components to be mounted is accumulated in the component information DB23, but information necessary for displaying the identification mark includes weight information on every circuit component, and reference position information. The weight information is predetermined based on a standard and specification for every circuit component. Further, the reference position information is information concerning respective center positions of the circuit components, and in the case of, for example, a resistor 31 as shown in FIG. 6, if lead wires installed at both ends thereof, respectively, are mounted up to attachment holes 32 bored in the printed board, respectively, the reference position information includes information on a straight line distance d from a position Q (indicated by symbol x) of the attachment hole on the left side up to the center position P (indicated by symbol x). That is, the reference position information is information showing a distance from respective attachment positions to the respective center positions serving as reference for the printed board, being expressed in terms of distance, angle, and so forth.

The mount information DB24 is based on design information such as kinds of the circuit components mounted on the printed board, mount positions on the printed board, and so forth, and information varying by the printed board is accumulated therein. For example, in the case where two resistors R1, R2 are mounted on a printed board 1 as shown in FIG. 7, the coordinates of attachment positions Q1, Q2, with reference to an angle O of the printed board 1, serving as references for the resistors R1, R2, respectively, are determined. The coordinates (X1, Y1) of the attachment position Q1, coordinates (X2, Y2) of the attachment position Q2, and attachment angles θ of the respective resistors are stored as the mount information.

On the basis of the reference position information and the mount information, the coordinates of the center positions of the respective circuit components, on the printed board, are calculated, and respective weights at the coordinates are found from the weight information on the circuit components. By carrying out calculation on all the circuit components to be mounted, weight distribution of the printed board as a whole can be found.

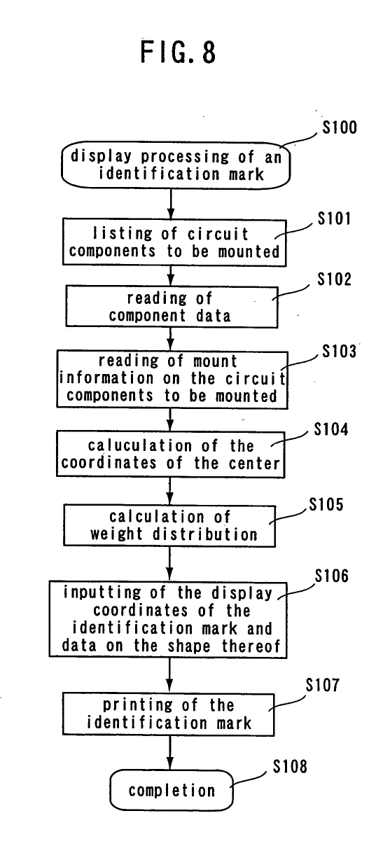

In FIG. 8, there is shown a flow chart concerning the display processing of the identification mark. Upon the start of display processing of the identification mark (step S100), listing processing of circuit components to be mounted on the printed board is executed (step S101). Subsequently, component data such as the weight information and the reference position information, concerning the circuit components to be mounted as listed, are read (step S102), and further, the mount information on the circuit components to be mounted are read (step S103). The coordinates of the center positions of the respective circuit components, on the printed board, as read, are calculated (step S104). For example, in FIG. 7, the coordinates of the center position P1 of the resistor R1 are calculated as (X1+d1, Y1), and the coordinates of the center position P2 of the resistor R2 are calculated as (X2, Y2+d2). Weights of the respective circuit components are assigned to the coordinates of the center positions of the respective circuit components, as found above, thereby finding weight distribution (step S105). Display processing of the weight distribution as found is executed by use of the monitor to thereby examine at which position on the printed board the identification mark is to be displayed, and in which shape the identification mark is to be displayed, and subsequently, input processing is executed (step S106) as to the coordinates of the display position of the identification mark and data on the shape thereof, whereupon the printing unit is caused to print the identification mark on the printed board (step S107). Then, completion processing is executed (step S108). The above-described steps of processing can be executed even in conjunction with designing of the printed board.

As described in the foregoing, with the method according to the invention, the display processing of the identification mark can be executed without actually taking measurements of the printed board with the circuit components mounted thereon, so that the method can be carried out with ease during a conventional work process.

1. A printed board with circuit components mounted thereon, wherein there is displayed an identification mark related to weight distribution in the printed board as a whole, calculated on the basis of weight information and reference position information, on the circuit components, and design information concerning respective mount positions of the circuit components.

2. A printed board according to claims 1, wherein the identification mark is displayed in relation to the weight distribution, along a conveyance direction of the printed board, in a solder tank.

3. A printed board according to claims 2, wherein the identification is displayed in a part along one side of the printed board, indicating the leading end side or the rear end side, in the conveyance direction.

4. A printed board according to claims 2, wherein the identification mark is displayed so as to pass through the heaviest part in terms of the weight distribution, thereby indicating the conveyance direction.

5. A method of displaying an identification mark comprises the steps of:
reading weight information and reference position information, on circuit components to be mounted on a printed board, and design information concerning mount positions of the respective circuit components;
calculating set position information on the printed board, on the basis of the design information and the reference position information;
calculating weight distribution information of the printed board, on the basis of the set position information and the weight information; and
displaying the identification mark on the printed board, on the basis of the weight distribution information.
